(19) United States
(12) Patent Application Publication
(10) Pub. No.: US 2009/0312981 A1
(43) Pub. Date: Dec. 17, 2009

(54) ALIGNMENT MARK AND ALIGNMENT METHOD USING THE ALIGNMENT MARK

(75) Inventor: Toshiya SAITO, Tokyo (JP)

Correspondence Address: YOUNG & THOMPSON, 209 Madison Street, Suite 500, Alexandria, VA, 22314, US

(73) Assignee: Elpida Memory, Inc., Tokyo (JP)

(21) Appl. No.: 12/483,473

(22) Filed: Jun. 12, 2009

(30) Foreign Application Priority Data
Jun. 13, 2008 (JP) 2008-155337

(51) Int. Cl. G06F 15/00; H01L 23/544

(52) U.S. Cl. 702/150; 257/797; 257/E23.179

(57) ABSTRACT

An alignment mark structure includes a first pair of first side walls and a second pair of second side walls. The first pair of first side walls faces each other and extends in a first direction. The first pair of first side walls crosses a first data detection line. The second pair of second side walls faces each other and extends in a second direction being different from the first direction. The second pair of second side walls crosses the first data detection line.

### BACKGROUND OF THE INVENTION

1. Field of the Invention

The present invention generally relates to an alignment mark and an alignment method using the alignment mark. More specifically, the present invention relates to an alignment mark that allows a highly accurate alignment and an alignment method at a high accuracy.

Priority is claimed on Japanese Patent Application No. 2008-155337, filed Jun. 13, 2008, the content of which is incorporated herein by reference.

2. Description of the Related Art

In general, semiconductor manufacturing processes include lithography processes. The lithography process may be performed by using a finder pattern or an alignment mark for detection of alignment. In general, the finder pattern may have a rectangular shaped step in cross sectioned view. The rectangular shaped step in cross sectioned view causes the peak of light intensity. The peak of light intensity is detected to determine the alignment coordination.

In the manufacturing process for semiconductor device, after the finder pattern is formed, then other processes can be performed, which may include, but are not limited to, processes for forming films or layers, anisotropic dry etching processes, and chemical mechanical polishing processes. Change in the shape of the step of the finder pattern will decrease the accuracy in the alignment coordination. This means that if the other processes are performed to change the shape of the step of the finder pattern, then the accuracy in the alignment coordination is decreased. Uniform change to the shape of the step of the finder pattern is unlikely to decrease the accuracy in the alignment coordination. Non-uniform change to the shape of the step of the finder pattern is likely to decrease the accuracy in the alignment coordination.

For example, the processes for forming films or layers, or the anisotropic dry etching processes are likely to cause uniform change to the shape of the step of the finder pattern. Uniform change to the shape of the step of the finder pattern is unlikely to decrease the accuracy in the alignment coordination. In contrast, the chemical mechanical polishing processes are likely to cause non-uniform change to the shape of the step of the finder pattern. Non-uniform change to the shape of the step of the finder pattern is likely to decrease the accuracy in the alignment coordination. When the chemical mechanical polishing process is performed after the finder pattern is formed, the shape of the step of the finder pattern is non-uniformly changed, thereby decreasing the accuracy in the alignment coordination. Decreases in the accuracy of the alignment coordination will cause miss-alignment of the finder pattern.

### SUMMARY

In one embodiment, an alignment mark structure may include, but is not limited to, a first pair of first side walls and a second pair of second side walls. The first pair of first side walls faces each other and extends in a first direction. The first pair of first side walls crosses a first data detection line. The second pair of second side walls faces each other and extends in a second direction being different from the first direction. The second pair of second side walls crosses the first data detection line.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentary plan view illustrating an alignment mark structure that is placed over a semiconductor substrate in accordance with a first embodiment of the present invention;

FIG. 1B is a diagram illustrating the peaks of signal intensity over signal coordination for the alignment mark structure shown in FIG. 1A;

FIG. 2A is a plan view illustrating a positional relationship between a polishing pad and a semiconductor chip of a semiconductor substrate in accordance with the first embodiment of the present invention;

FIG. 2B is a fragmentary enlarged plan view illustrating the semiconductor chip shown in FIG. 2A;

FIG. 2C is a fragmentary enlarged plan view illustrating the semiconductor chip shown in FIG. 2A;

FIG. 3A is a cross sectional elevation view illustrating a chemical mechanical polishing apparatus that can be used for carrying out the chemical mechanical polishing process in accordance with the first embodiment of the present invention;

FIG. 3B is a plan view illustrating the chemical mechanical polishing apparatus of FIG. 3A;

FIG. 4 is a plan view illustrating another alignment mark structure that includes a plurality of first groove parts and a plurality of second groove parts in accordance with another embodiment of the present invention;

FIG. 5 is a plan view illustrating still another alignment mark structure that includes a plurality of first groove parts and a plurality of second groove parts in accordance with still another embodiment of the present invention;

FIG. 6 is a cross sectional elevation view illustrating an example of a finder pattern that is not deformed yet before a chemical mechanical polishing process is performed in accordance with the related art;

FIG. 7A is a cross sectional elevation view illustrating the example of the finder pattern that is deformed by performing the chemical mechanical polishing process in accordance with the related art;

FIG. 7B is a diagram showing the peaks of optical signal intensity on the signal coordinate belonging to the deformed finder pattern of FIG. 7A;

FIG. 8A is a cross sectional elevation view illustrating an ideal example of the finder pattern that is not deformed even after the chemical mechanical polishing process is performed in accordance with the related art;

FIG. 8B is a diagram showing the peaks of optical signal intensity on the signal coordinate belonging to the finder pattern of FIG. 8A;

FIG. 9A is a cross sectional elevation view illustrating a finder pattern that has not yet been polished by a chemical mechanical polishing process, in order to describe the phenomenon of dishing in accordance with the related art;

FIG. 9B is a cross sectional elevation view illustrating an finder pattern that has been polished by the chemical mechanical polishing process, in order to describe the phenomenon of dishing in accordance with the related art;

FIG. 10A is a cross sectional elevation view illustrating a finder pattern that has not yet been polished by a chemical mechanical polishing process, in order to describe the phenomenon of erosion in accordance with the related art;

FIG. 10B is a cross sectional elevation view illustrating an finder pattern that has been polished by the chemical mechanical polishing process, in order to describe the phenomenon of erosion in accordance with the related art;

FIG. 11A is a plan view illustrating a finder pattern in the related art;

FIG. 11B is a diagram illustrating detected peaks of the light intensity of the finder pattern shown in FIG. 11A;

FIG. 12A is a plan view illustrating one relationship between the tangential line of the rotational direction of the polishing pad and the side walls of the recesses to be polished in accordance with the related art; and

FIG. 12B is a plan view illustrating another relationship between the tangential line of the rotational direction of the polishing pad and the side walls of the recesses to be polished in accordance with the related art.

### DETAILED DESCRIPTION OF THE PREFERRED EMBODIMENTS

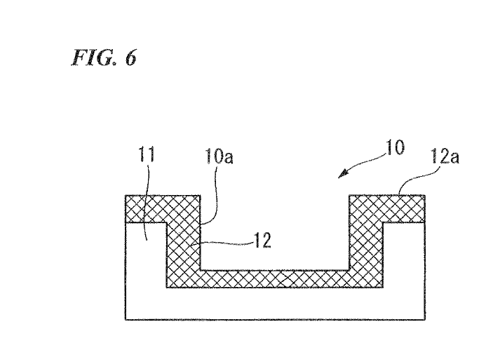

Before describing the present invention, the related art will be explained in detail with reference to FIGS. 6, 7A, 7B, 8A, 8B, 9A, 9B, 10A, 10B, 11A, 11B, 12A and 12B, in order to facilitate the understanding of the present invention. When the chemical mechanical polishing process is performed after the finder pattern is formed, the shape of the step of the finder pattern is non-uniformly changed, thereby decreasing the accuracy in the alignment coordination. Decreases in the accuracy of the alignment coordination will cause miss-alignment of the finder pattern. The following description will focus on how the chemical mechanical polishing process deforms the finder pattern.

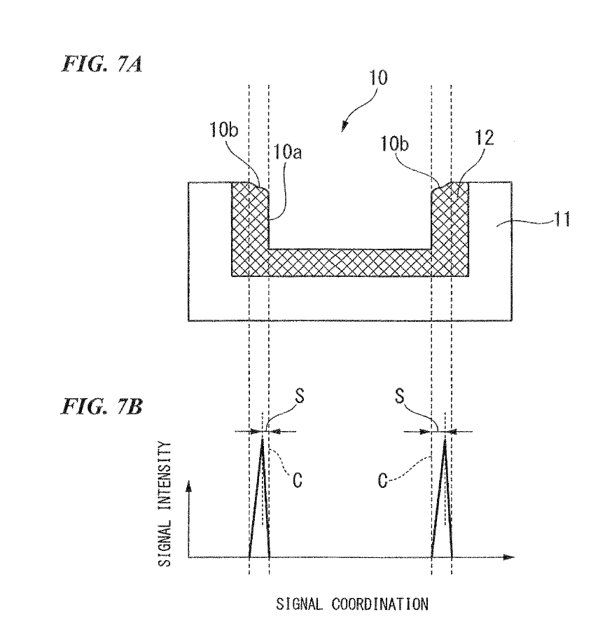

FIG. 6 is a cross sectional elevation view illustrating an example of a finder pattern that is not deformed yet before a chemical mechanical polishing process is performed. FIG. 7A is a cross sectional elevation view illustrating the example of the finder pattern that is deformed by performing the chemical mechanical polishing process. FIG. 7B is a diagram showing the peaks of optical signal intensity on the signal coordinate belonging to the deformed finder pattern of FIG. 7A. The peaks of the optical signal intensity are detected by scanning or measuring the intensity of a light along a data detection line or a section line of the finder pattern.

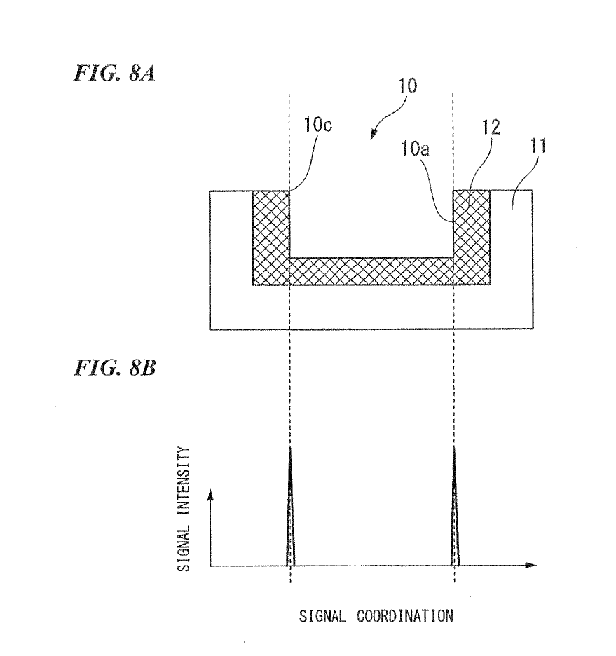

FIG. 8A is a cross sectional elevation view illustrating an ideal example of the finder pattern that is not deformed even after the chemical mechanical polishing process is performed. FIG. 8B is a diagram showing the peaks of optical signal intensity on the signal coordinate belonging to the finder pattern of FIG. 8A. The peaks of the optical signal intensity are detected by scanning or measuring the intensity of a light along a data detection line or a section line of the finder pattern.

With reference to FIG. 6, a finder pattern 10 is provided over an oxide film 11. The oxide film 11 may constitute a part of a semiconductor substrate that is not illustrated. The finder pattern 10 is made of a polishable material 12 such as tungsten (W). The finder pattern 10 may have a recess 10a and a polished surface 12a. The recess 10a and the polished surface 12a are bounded by a sharp-edged step as shown in FIG. 6.

The recess 10a has a rectangular shape in the cross sectional view. The recess 10a has a depth that is deeper than a polishing depth by which the polished surface 12a is to be polished. The polishing depth may be a thickness of the polishable material 12 that provides the polished surface 12a. Namely, the polishable material 12 has a first part which provides the polished surface 12a and a second part which provides the recess 10a.

After the finder pattern 10 is formed over the oxide film, then the chemical mechanical polishing process is carried out to polish the polished surface 12a and remove the first part which provides the polished surface 12a. With reference to FIG. 7A, the chemical mechanical polishing process is carried out until the oxide film 11 is exposed and the first part of the polishable material 12 is removed, while the second part of the polishable material 12 remains in the recess 10a. After the chemical mechanical polishing process is carried out, the polishable material 12 has a deformed step 10b that is deformed from the sharp-edged step. A typical example of the deformed step 10b is shown in FIG. 7A. The deformed step 10b is caused by the polishing.

FIG. 8A shows an ideal example of the finder pattern that is deformed by performing the chemical mechanical polishing process. With reference to FIG. 8A, the chemical mechanical polishing process is carried out until the oxide film 11 is exposed and the first part of the polishable material 12 is removed, while the second part of the polishable material 12 remains in the recess 10a. After the chemical mechanical polishing process is carried out, the polishable material 12 has a sharp edged step 10c. Atypical example of the sharp-edged step 10c is shown in FIG. 7A. In general, the sharp-edged step 10c has a right angle. The sharp-edged step 10c has no deformation.

FIG. 7B is a diagram showing the peaks of optical signal intensity on the signal coordinate belonging to the deformed finder pattern of FIG. 7A. FIG. 8B is a diagram showing the peaks of optical signal intensity on the signal coordinate belonging to the finder pattern of FIG. 8A. The peaks of the signal intensity of FIG. 8B is more sharp and narrower than the peaks of the signal intensity of FIG. 7B.

As shown in FIG. 8B, the sharp-edged step 10c causes a sharp and narrow peak of the signal intensity. The sharp and narrow peak is positioned just at the sharp-edged step 10c or the side wall of the recess 10a.

As shown in FIG. 7B, the deformed step 10b causes a broad peak of the signal intensity. The broad peak has a shift S from a position C which corresponds to the side wall of the recess 10a. The shift S depends on the deformation of the deformed step 10b. As the deformation of the deformed step 10b is larger, the shift S of the peak of the signal intensity is larger. The shift S of the peak of the signal intensity deteriorates the accuracy of the alignment coordination. In other words, the broad peak of the signal intensity deteriorates the accuracy of the alignment coordination.

The deformation of the step 10b of the finder pattern may be, for example, caused by some phenomenon such as dishing or erosion. The phenomenon of dishing or erosion will be described in detail with reference to the drawings.

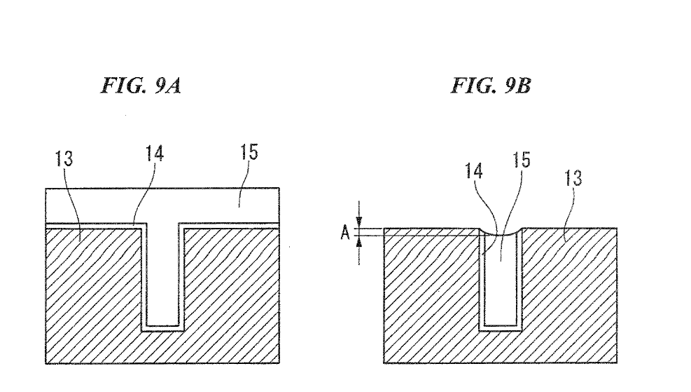

FIG. 9A is a cross sectional elevation view illustrating a finder pattern that has not yet been polished by a chemical mechanical polishing process, in order to describe the phenomenon of dishing. FIG. 9B is a cross sectional elevation view illustrating an finder pattern that has been polished by the chemical mechanical polishing process, in order to describe the phenomenon of dishing. The finder pattern includes a silicon oxide film 13 such as a silicon dioxide film. The silicon oxide film 13 has a trench groove. The surface of the silicon oxide film 13 is coated by a TiN/Ti film 14. The TiN/Ti film 14 covers the surface of the silicon oxide film 13. A tungsten film 15 covers the TiN/Ti film 14. A chemical mechanical polishing process is carried out to polish the tungsten film 15 and the TiN/Ti film 14. The tungsten film 15 and the TiN/Ti film 14, which extend over the top surface of the silicon oxide film 13, are removed, while the tungsten film 15 and the TiN/Ti film 14 remain the trench groove of the silicon oxide film 13. The top surface of the silicon oxide film 13 is thus exposed, wherein the tungsten film 15 within the trench groove has a concave surface like a dish. The concave surface has a depth “A” shown in FIG. 9B. This phenomenon is called “dishing”.

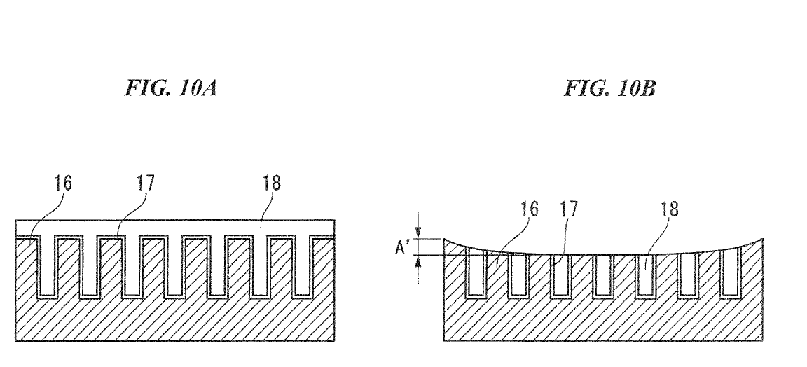

FIG. 10A is a cross sectional elevation view illustrating a finder pattern that has not yet been polished by a chemical mechanical polishing process, in order to describe the phenomenon of erosion. FIG. 10B is a cross sectional elevation view illustrating an finder pattern that has been polished by the chemical mechanical polishing process, in order to describe the phenomenon of erosion. The finder pattern includes an insulating film 16 such as a silicon dioxide film. The silicon oxide film 13 has trench grooves. The surface of the insulating film 16 is coated by a TiN/Ti film 17. The TiN/Ti film 17 covers the surface of the insulating film 16. A tungsten film 18 covers the TiN/Ti film 16. A chemical mechanical polishing process is carried out to polish the tungsten film 18 and the TiN/Ti film 17. The tungsten film 18 and the TiN/Ti film 17, which extend over the top surface of the silicon oxide film 13, are removed, while the tungsten film 18 and the TiN/Ti film 17 remain the trench grooves of the insulating film 16. The upper surface of the insulating film 16 is thus exposed, wherein the upper surface of the insulating film 16 has a concave surface like a dish. The concave surface extends over the entirety of the insulating film 16 that have the trench grooves. The concave surface has a depth “A′” shown in FIG. 10B. This phenomenon is called “erosion”. No phenomenon of “erosion” is caused when the density of pattern of the finder pattern is low. No phenomenon of “erosion” is caused with non-dense pattern.

For example, Japanese Unexamined Patent Application, First Publication, No. 2000-200751 discloses a technique as a countermeasure against the deformation of the finder pattern, wherein the deformation is caused by the chemical mechanical polishing process. Mesa patterns or trench patterns are discontinuously aligned at a lower density as to cause no phenomenon of dishing.

Japanese Unexamined Patent Application, First Publication, No. 2000-306822 discloses another technique as another countermeasure against the deformation of the finder pattern, wherein the deformation is caused by the chemical mechanical polishing process. A target is used for alignment, wherein the target has lines, each of which is formed by a dotted pattern.

Japanese Unexamined Patent Application, First Publication, No. 2000-208392 discloses an alignment mark structure that includes an alignment mark and dummy patterns. The dummy patterns are disposed around the alignment mark. The dummy patterns are used to protect the alignment mark from being polished by the chemical mechanical polishing process.

Japanese Unexamined Patent Application, First Publication, No. 05-166772 discloses a technique as follows. A groove for a base pattern is formed using a mask having an opening of cross-shape, while forming isolation grooves. A n oxide film is formed over the groove for the base pattern and over the isolation grooves. A polysilicon film is then formed over the oxide film. A polishing process is carried out so that a cross-shaped base pattern made of polysilicon is exposed over the polished surface of the substrate, wherein the cross-shaped base pattern is surrounded by the oxide film.

Those techniques need to be improved to improve the accuracy of alignment. For example, the alignment marks of irregular alignments of mesa patterns or trench patterns have such a high density of patterns as to cause the phenomenon of erosion even no dishing is caused. The phenomenon of erosion causes deformation of the alignment mark. The use of the deformed alignment mark can not avail any accurate signal coordination. The mesa patterns or the trench patterns are irregularly aligned at such a density as to cause no phenomenon of dishing. This leads to the use of position coordinate of deformable portions that are proximal to the corners of the mesa pattern or the trench pattern. No high accuracy of alignment is obtained.

An alignment mark structure is desirable, which allows a highly accurate alignment The alignment mark structure can provide highly accurate alignment coordination. The alignment mark structure is desirably free from the deformation of a finding pattern due to the chemical mechanical polishing process. An alignment method is desirable, which allows a highly accurate alignment using an alignment mark structure.

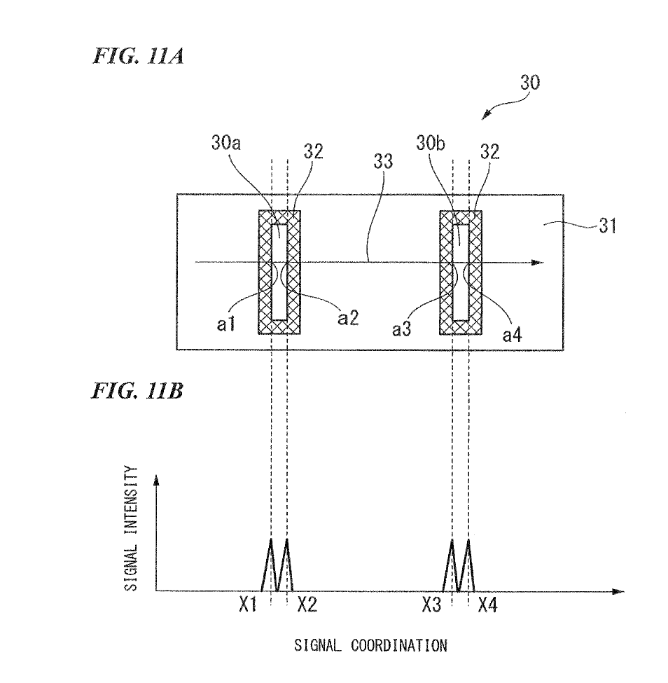

The relationship of an edge-deformation of a finder pattern and the amount of shift of detection data due to its edge-deformation has been investigated. In general, the chemical mechanical polishing process is carried out by rotating a polishing pad and a polishing head in a direction. Thus, the amount of shift of detection data due to the edge-deformation of the finder pattern varies depending upon the rotational direction of the polishing pad in the chemical mechanical polishing process. The relationship of the rotational direction of the polishing pad and the amount of shift of detection data due to the edge-deformation of the finder pattern will be described with reference to FIGS. 11A and 11B. FIG. 11A is a plan view illustrating a finder pattern in the related art. FIG. 11B is a diagram illustrating detected peaks of the light intensity of the finder pattern shown in FIG. 11A. The detection of the light intensity is measured along a data detection line 33 in FIG. 11A. In FIG. 11B, the vertical axis represents the signal intensity and the horizontal axis represents the signal coordination.

As shown in FIG. 11A, the finder pattern 30 may be made of a polishable material 32 such as tungsten (W). The finder pattern 30 has first and second recesses 30a and 30b which extend in parallel to each other in a direction perpendicular to the data detection line 33. The polishable material 32 is polished by the chemical mechanical polishing process so that an oxide film 31 over a substrate surface is exposed. The stepped-edges a1, a2, a3 and a4 of the side walls of the first and second recesses 30a and 30b are also polished and deformed. Namely, the first and second recesses 30a and 30b have deformed edges a1, a2, a3 and a4 at the tops of the side walls thereof, wherein the deformation was caused by the chemical mechanical polishing process.

It was confirmed by the inventor that the deformed edges a1 and a3 of the first and second recesses 30a and 30b cause broadening of the peaks of the signal intensity thereby causing the shift of detection data as shown in FIG. 11B as well as that the deformed edges a2 and a4 of the first and second recesses 30a and 30b cause broadening of the peaks of the signal intensity thereby causing the shift of detection data as shown in FIG. 11B.

It was confirmed by the inventor the followings. The recesses 30a and 30b have side walls that are positioned in the downstream side of the rotational direction of the polishing pad in the chemical mechanical polishing process. These downstream-side side walls are polished by the polishing pads that are deformed by the recesses 30a and 30b. The deformation of the polishing pads due to the recesses 30a and 30b causes increasing the amount of shift of the detection data at the deformed edges of the downstream-side side walls of the recesses 30a and 30b.

With reference again to FIG. 11A, the finder pattern 30 has the first and second recesses 30a and 30b which extend in parallel to each other in the direction perpendicular to the data detection line 33. It is assumed that the tangential line of the rotational direction of the polishing pad as shown in FIG. 11A is directed in the direction of the data detection line 33 from the left to the right. The downstream-side side walls of the recesses 30a and 30b, which are positioned in the downstream side of the rotational direction of the polishing pad in the chemical mechanical polishing process, are polished by the deformed polishing pads, so that the stepped-edges of the downstream-side side walls of the recesses 30a and 30b are deformed. As a result of the chemical mechanical polishing process, the downstream-side side walls of the recesses 30a and 30b of the recesses 30a and 30b have deformed edges a2 and a4. The deformed edges a2 and a4 cause increasing the shift amount of the peaks of the signal intensity. The chemical mechanical polishing process is carried out so that the surface of the substrate is pressed to the polishing pad that is rotating, wherein the polishing pad is deformed. The deformation of the polishing pad causes the deformation of the stepped-edges of the downstream-side side walls of the recesses 30a and 30b.

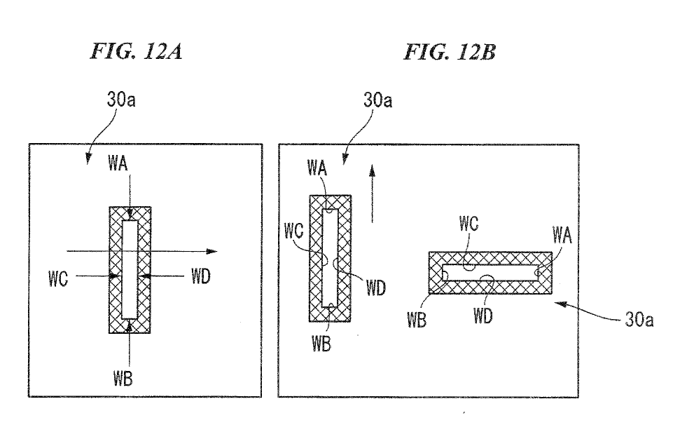

A further investigation was made about the relationship between the tangential line of the rotational direction of the polishing pad and the side walls of the recesses to be polished. FIG. 12A is a plan view illustrating one relationship between the tangential line of the rotational direction of the polishing pad and the side walls of the recesses to be polished. FIG. 12B is a plan view illustrating another relationship between the tangential line of the rotational direction of the polishing pad and the side walls of the recesses to be polished. In FIGS. 12A and 12B, the recess 30a has four side walls WA, WB, WC and WD. The four side walls WA, WB, WC and WD are positioned so that the four side walls WA, WB, WC and WD form a rectangular shape in plan view.

As shown in FIG. 12A, the tangential line of the rotational direction of the polishing pad is directed by the arrow mark line. The side wall WD is positioned in the downstream side of the polishing pad that is rotating. The side wall WD extends in the direction that is perpendicular to the arrow mark line. The polishing pad being rotating is deformed by the recess 30a. The side wall WD is positioned in the downstream side of the polishing pad that is rotating. Immediately after the surface of the polishing pad passes the recess 30a, the surface of the polishing pad becomes contact tightly with the side wall WD and polishes the side wall WD strongly. Thus, the stepped edge of the side wall WD is largely deformed. The large deformation of the stepped edge causes the large amount of shift of the detection data.

The side walls WA and WB extend parallel to the arrow mark line or the tangential line of the rotational direction of the polishing pad. The surface of the polishing pad polishes the side walls WA and WB less strongly than the side wall WD. Thus, the stepped edges of the side walls WA and WB are less deformed than the deformation of the stepped edge of the side wall WD. The amount of the shift of the detection data at the edges of the side walls WA and WB is smaller than the amount of the shift of the detection data at the deformed edge of the side wall WD. Namely, if the tangential line of the rotational direction of the polishing pad is perpendicular to the data detection line of the finder pattern, then the deformation of the stepped edge of the side wall is smaller. Thus, the stepped edges of the side walls WA and WB are less deformed than the deformation of the stepped edge of the side wall WD. The amount of the shift of the detection data at the edges of the side walls WA and WB is smaller than the amount of the shift of the detection data at the deformed edge of the side wall WD.

In the chemical mechanical polishing process, the polishing head is rotating and the semiconductor substrate is rotating. As shown in FIG. 12B, the arrow mark is directed from the bottom to the top. First and second recesses 30a are disposed. The first recess 30a is positioned left side of the second recess 30a. The first recess 30a has a longitudinal direction that is parallel to the arrow mark. The second recess 30a has a longitudinal direction that is perpendicular to the arrow mark. The tangential line of the rotating direction of the polishing pad is directed in the same direction as the arrow mark.

For the first recess 30a, the side wall WA of the recess 30a is largely deformed as compared to the other side walls WB, WC and WD because the side wall WA is positioned downstream the rotational direction of the polishing pad that is rotating, and because the side wall WA extends in a direction perpendicular to the tangential line of the rotational direction of the polishing pad.

For the second recess 30a, the side wall WC of the recess 30a is largely deformed as compared to the other side walls WA, WB, and WD because the side wall WC is positioned downstream the rotational direction of the polishing pad that is rotating, and because the side wall WC extends in a direction perpendicular to the tangential line of the rotational direction of the polishing pad.

Except when the side wall extends in a direction that is neither parallel nor perpendicular to the direction the tangential line of the rotational direction of the polishing pad, the direction along which the side wall extends crosses the tangential line of the rotational direction of the polishing pad. The position and amount of deformation of the stepped-edge of the side wall depend upon a placement angle that is defined between a direction along which the side wall extends and another direction of the tangential line of the rotational direction of the polishing pad.

Investigations have been made on the relationship between the shape of the alignment mark structure and the placement of the data detection line that shows the measuring position at which the positional coordination of the alignment mark structure. A particular structure is desired which cancel influences caused by the position and amount of deformation of the stepped-edge of the side wall that depend on the placement angle of the side wall. An alignment method is desired which cancel influences caused by the position and amount of deformation of the stepped-edge of the side wall that depend on the placement angle of the side wall.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

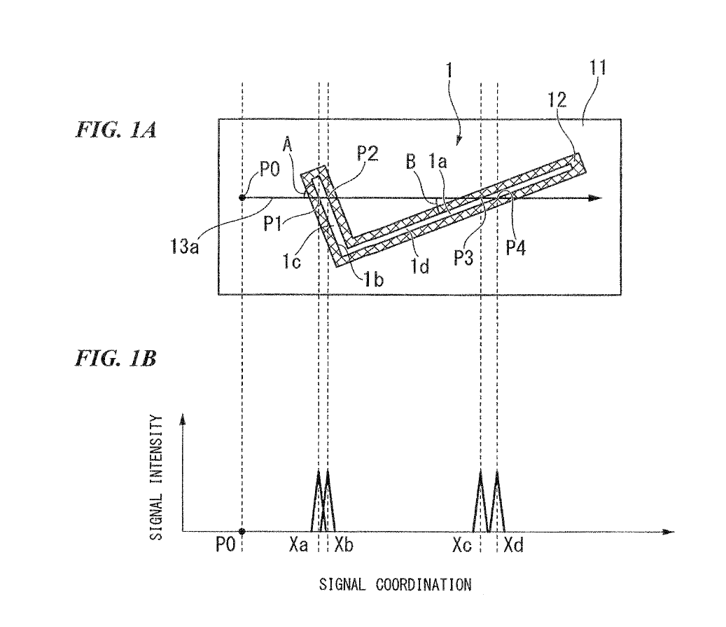

FIG. 1A is a fragmentary plan view illustrating an alignment mark structure that is placed over a semiconductor substrate in accordance with a first embodiment of the present invention. FIG. 1B is a diagram illustrating the peaks of signal intensity over signal coordination for the alignment mark structure shown in FIG 1A.

An alignment mark structure 1 is provided over an oxide film 11 that covers a semiconductor substrate. The alignment mark structure 1 may be made of a polishable material 12. Atypical example of the polishable material 12 may include, but is not limited to, tungsten (W). The polishable material 12 may have a groove 1a. The groove 1a may be defined by a pair of side walls. The groove 1a may have a rectangle shape in cross sectional view.

The groove 1a of the alignment mark structure 1 may include, but is not limited to, a first groove part 1c and a second groove part 1d. The first groove part 1c extends in a first direction. The second groove part 1d extends in a second direction that is different from the first direction. The first groove part 1c may be defined by a first pair of first side walls. The second groove part 1d may be defined by a second pair of second side walls. In some cases, the first groove part 1c may continuously be coupled to the second groove part 1d as shown in FIG. 1A. In other cases, the first groove part 1c may be separated from the second groove part 1d. The first groove part 1c may include a first pair of side walls that extend in parallel to the first direction. The second groove part 1d may include a second pair of side walls that extend in parallel to the second direction. In some cases, the second direction is perpendicular to the first direction.

In some cases, the second groove part 1d may be longer than the first groove part 1c. The second groove part 1d may be coupled with the first groove part 1c. The first and second groove parts 1c and 1d may form an L-shape in plan view.

In other cases, the second groove part 1d may be shorter than the first groove part 1c. The second groove part 1d may be separated from the first groove part 1c. In still other cases, the second groove part 1d may have the same length as the first groove part 1c.

With reference to FIG. 1A, a data detection line 13a runs across the first and second groove parts 1c and 1d. The data detection line 13a is used to detect positional coordination points of the alignment mark structure 1. The alignment mark structure 1 has the groove 1a that is defined by the pair of side walls. The groove 1a of the alignment mark structure 1 has stepped-edges that are positioned directly over the side walls. The positions of the stepped-edges or the side walls are detected by a measuring apparatus. The groove 1a is defined by the side walls that have top edges 1b that are polished. The top edges 1b have deformation that is caused by polishing process.

With reference to FIG. 1A, the data detection line is represented by the arrow mark 13a. The arrow mark 13a is directed from the left to the right. The tangential line of the rotational direction of the polishing pad 25 is parallel to the arrow mark 13a.

The first groove part 1c has a first angle A with reference to the data detection line 13a. The first angle A may be 60 degrees. The first groove part 1c extends in the first direction. The first angle A is defined between the first direction and the data detection line 13a. The second groove part 1d has a second angle B with reference to the data detection line 13a. The second angle B may be 30 degrees. The second groove part 1d extends in the second direction. The second angle B is defined between the second direction and the data detection line 13a. The first and second groove parts 1c and 1d have an included angle which is 90 degrees. The first angle A may be in the range of 20 degrees to 70 degrees. If the first angle A is out of the range of 20 degrees to 70 degrees, then it is possible that the error of the detection of the alignment mark is significant. The first angle A may be most preferable to improve the accuracy of the alignment as much as possible.

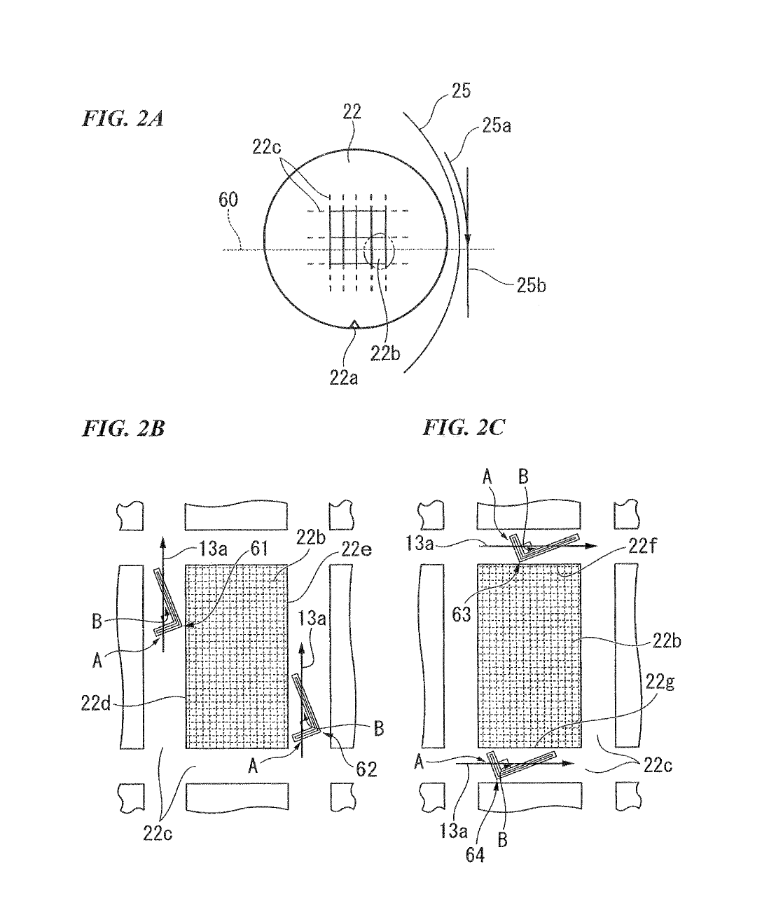

FIG. 2A is a plan view illustrating a positional relationship between a polishing pad and a semiconductor chip of a semiconductor substrate, wherein a notch of the semiconductor substrate is positioned to face toward a tangential line of a rotational direction of the polishing pad. A polishing pad 25 polishes a semiconductor substrate 22. The semiconductor substrate 22 has a notch 22a. FIG. 2A illustrates that the notch 22a is positioned to face toward a tangential line 25b of a rotational direction 25a of the polishing pad 25. The semiconductor substrate 22 includes an array of semiconductor chips 22b, each of which is defined by scribe lines 22c. The semiconductor chip 22b may be shaped in a rectangle. When the notch 22a is positioned to face toward the tangential line 25b of the rotational direction 25a of the polishing pad 25, edge lines extend in parallel to each other in the left and right side of the semiconductor chip 22b. In this case, the edge lines are vertical to a horizontal center line 60 that runs on the center of the polishing pad 25. The edge lines are parallel to the tangential line 25b of the rotational direction 25a of the polishing pad 25. If the semiconductor substrate 22 rotates by 90 degrees, 180 degrees, and 270 degrees, then the edge lines are vertical to the horizontal center line 60 that runs on the center of the polishing pad 25. The edge lines are parallel to the tangential line 25b of the rotational direction 25a of the polishing pad 25.

FIG. 2B is a fragmentary enlarged plan view illustrating the semiconductor chip shown in FIG. 2A. The semiconductor chip 22b is surrounded by the scribe lines 22c. The semiconductor chip 22b is separated by the scribe lines 22c from the other semiconductor chip 22b. The semiconductor chip 22 has a first-side edge line 22d and a second-side edge line 22e. The first-side edge line 22d and the second-side edge line 22e are first opposing sides of the rectangle of the semiconductor chip 22b. A first alignment mark 61 is provided on the scribe line 22c that is adjacent to the first-side edge line 22d of the semiconductor chip 22. A second alignment mark 62 is provided on the scribe line 22c that is adjacent to the second-side edge line 22e of the semiconductor chip 22. The first and second alignment marks 61 and 62 are disposed in a direction that is different by 90 degrees from the alignment mark structure 1 shown in FIG. 1A.

The first and second alignment marks 61 and 62 are disposed across the data detection lines 13a. The data detection lines 13a are parallel to the first-side edge line 22d and the second-side edge line 22e of the semiconductor chip 22b. In the state shown in FIG. 2A, the data detection line 13a is parallel to the tangential line 25b of a rotational direction 25a of the polishing pad 25. Each of the first and second alignment marks 61 and 62 includes the first groove part 1c and the second groove part 1d. The first groove part 1c extends across the data detection line 13a. The first groove part 1c extends in the first direction that is not parallel to the data detection line 13a. The first groove part 1c has the first angle A with reference to the data detection line 13a. The first groove part 1c extends not parallel to the tangential line 25b of a rotational direction 25a of the polishing pad 25. The first groove part 1c and the data detection line 13a have the first angle A as the included angle. The first angle A is 60 degrees. The second groove part 1d extends across the data detection line 13a. The second groove part 1d extends in the second direction that is not parallel to the data detection line 13a. The second groove part 1d has the second angle B with reference to the data detection line 13a. The second groove part 1d and the data detection line 13a have the second angle B as the included angle. The second angle B is 30 degrees. The second groove part 1d extends non-parallel to the tangential line 25b of a rotational direction 25a of the polishing pad 25.

FIG. 2C is a fragmentary enlarged plan view illustrating the semiconductor chip shown in FIG. 2A. The semiconductor chip 22b is surrounded by the scribe lines 22c. The semiconductor chip 22b is separated by the scribe lines 22c from the other semiconductor chip 22b. The semiconductor chip 22 has a third-side edge line 22f and a fourth-side edge line 22g. The third-side edge line 22f and the fourth-side edge line 22g are second opposing sides of the rectangle of the semiconductor chip 22b. A third alignment mark 63 is provided on the scribe line 22c that is adjacent to the third-side edge line 22f of the semiconductor chip 22. A fourth alignment mark 64 is provided on the scribe line 22c that is adjacent to the fourth-side edge line 22g of the semiconductor chip 22. The third and fourth alignment marks 63 and 64 are disposed in the same direction as the alignment mark structure 1 shown in FIG. 1A.

The third and fourth alignment marks 63 and 64 are disposed across the data detection lines 13a. The data detection lines 13a are parallel to the third-side edge line 22f and the fourth-side edge line 22g of the semiconductor chip 22b. In the state shown in FIG. 2A, the data detection line 13a is parallel to the tangential line 25b of the rotational direction 25a of the polishing pad 25. Each of the third and fourth alignment marks 63 and 64 includes the first groove part 1c and the second groove part 1d. The first groove part 1c extends across the data detection line 13a. The first groove part 1c has the first angle A with reference to the data detection line 13a. The first groove part 1c extends non-parallel to the tangential line 25b of a rotational direction 25a of the polishing pad 25. The first groove part 1c and the data detection line 13a have the first angle A as the included angle. The first angle A is 60 degrees. The second groove part 1d extends across the data detection line 13a. The second groove part 1d extends in the second direction that is non-parallel to the data detection line 13a. The second groove part 1d has the second angle B with reference to the data detection line 13a. The second groove part 1d and the data detection line 13a have the second angle B as the included angle. The second angle B is 30 degrees. The second groove part 1d extends non-parallel to the tangential line 25b of the rotational direction 25a of the polishing pad 25.

FIG. 2B illustrates one example of providing the first and second alignment marks 61 and 62 adjacent to the first-side edge line 22d and the second-side edge line 22e of the semiconductor chip 22b. FIG. 2C illustrates another example of providing the third and fourth alignment marks 63 and 64 adjacent to the third-side edge line 22f and the fourth-side edge line 22g of the semiconductor chip 22b. In other cases, it is possible that the first, second, third and fourth alignment marks 61, 62, 63 and 64 are provided adjacent to the first-side edge line 22d, the second-side edge line 22e, the third-side edge line 22f and the fourth-side edge line 22g, respectively. The first, second, third, and fourth alignment marks 61, 62, 63 and 64 are disposed in the same direction. In one case, the first, second, third and fourth alignment marks 61, 62, 63 and 64 may be disposed with reference to the data detection line 13a that is parallel to the first-side edge line 22d and the second-side edge line 22e and is perpendicular to the third-side edge line 22f and the fourth-side edge line 22g as shown in FIG. 2B. In other case, the first, second, third and fourth alignment marks 61, 62, 63 and 64 may be disposed with reference to the data detection line 13a that is perpendicular to the first-side edge line 22d and the second-side edge line 22e and is parallel to the third-side edge line 22f and the fourth-side edge line 22g as shown in FIG. 2C. In any cases, the first, second, third and fourth alignment marks 61, 62, 63 and 64 may be disposed with reference to the data detection line 13a that is perpendicular to or parallel to each of the first-side edge line 22d, the second-side edge line 22e, the third-side edge line 22f and the fourth-side edge line 22g.

FIG. 1B is a diagram illustrating the peaks of optical signal intensity over signal coordination, which is measured on the alignment mark structure shown in FIG. 1A. A measuring apparatus is used to measure the optical signal intensity to determine the peaks of the optical signal intensity. A scanning is carried out along the data detection line 13a across which the alignment mark structure 1 extends. A specific position coordinate P0 is a starting position from which the scanning is made on the data detection line 13a. The alignment mark structure 1 is detected as follows. The alignment mark structure 1 has position coordinates Xa, Xb, Xc and Xd on the data detection line 13a. The position coordinates Xa, Xb, Xc and Xd correspond to positions P1, P2, P3 and P4 respectively of the alignment mark structure 1, wherein the positions P1, P2, P3 and P4 are crossing positions of the first side walls and the second side walls on the data detection line 13a. First to fourth distances of the position coordinates Xa, Xb, Xc and Xd from the specific position coordinate P0 are determined. An averaged distance of the first to fourth distances is calculated. The averaged distance is regarded as a distance of the groove 1a of the alignment mark structure 1 from the specific position coordinate P0.

The position coordinate Xa is a coordinate of the position P1, on the data detection line 13a, of the first side wall of the first groove part 1c of the alignment mark structure 1. The position coordinate Xb is a coordinate of the position P2, on the data detection line 13a, of the other first side wall of the first groove part 1c of the alignment mark structure 1.

The position coordinate Xc is a coordinate of the position P3, on the data detection line 13a, of the second side wall of the second groove part 1d of the alignment mark structure 1. The position coordinate Xd is a coordinate of the position P4, on the data detection line 13a, of the other second side wall of the second groove part 1d of the alignment mark structure 1.

The deformations of the stepped edges of the side walls of the groove 1a of the alignment mark structure 1 depend on the angle between the side walls and the tangential line of the rotational direction of the polishing pad 25. The sum of the shift amount of the position coordinate Xa and the shift amount of the position coordinate Xc is almost similar to the sum of the shift amount of the position coordinate Xb and the shift amount of the position coordinate Xd.

The averaged distance of the position coordinates Xa, Xb, Xc and Xd from the specific position coordinate P0 is detected when the stepped edges of the side walls of the groove 1a of the alignment mark structure 1 are deformed by the polishing process. The averaged distance when the deformation appears can be approximated to be an ideal-state averaged value that is obtained when no deformation is caused of the stepped edges of the side walls of the groove 1a. The ideal-state averaged value is an averaged value of first to fourth distances position coordinates Xa′, Xb′, Xc′ and Xd′ from the specific position coordinate P0 when no deformation is caused of the stepped edges of the side walls of the groove 1a. The amounts of the shifts caused at the position coordinates Xa, Xb, Xc and Xd can be cancelled by the amounts of the shifts caused at the position coordinates Xa′, Xb′, Xc′ and Xd′.

The following equations shows that the amounts of the shifts caused at the position coordinates Xa, Xb, Xc and Xd can be cancelled by the amounts of the shifts caused at the position coordinates Xa′, Xb′, Xc′ and Xd′.

$$\begin{matrix}\frac{\{ \frac{( Xa + Xc )}{2} + \frac{( Xb + Xd )}{2} \}}{2} = \frac{( Xa + Xc )}{4} + \frac{( Xb + Xd )}{4} \\ = \frac{[ ( {Xa}^{′} - α ) + \{ {Xc}^{′} - ( A - α ) \} ]}{4} + \\ \frac{[ ( {Xb}^{′} + β ) + \{ {Xd}^{′} + ( {A}^{′} - β ) \} ]}{4} \\ = \frac{( {Xa}^{′} + {Xc}^{′} - A )}{4} + \frac{( {Xb}^{′} + {Xd}^{′} + {A}^{′} )}{4} \\ = \frac{( {Xa}^{′} + {Xb}^{′} + {Xc}^{′} + {Xd}^{′} )}{4}\end{matrix}$$

The position coordinates Xa, Xb, Xc and Xd represent the first to fourth distances from the specific position coordinate P0 when the deformations are caused on the stepped edges of the side walls of the groove 1 a of the alignment mark structure 1. The position coordinates Xa′, Xb′, Xc′ and Xd′ represent the first to fourth ideal distances from the specific position coordinate P0 when no deformations are caused on the stepped edges of the side walls of the groove 1a of the alignment mark structure 1. α represents the shift amount included in Xa. B represents the shift amount included in Xb. A represents the sum of the shift amounts of the included in Xa and Xc. A′ represents the sum of the shift amounts of the included in Xb and Xd. A is nearly equal to A′.

The alignment mark structure 1 can be obtained as follows. A semiconductor substrate having a surface that is covered by an oxide film 11 is prepared. A groove 1a is formed in the oxide film 11. The groove 1a has a rectangle in cross sectional view. The groove 1a has an L-shape in plan view. A polishable material layer 12 is provided over the oxide film 11 having the groove 1a. The polishable material layer 12 may be made of a polishable material such as tungsten W. A polishing process such as a chemical mechanical polishing process is carried out to polish and remove partially the polishable material layer 12 until the oxide film 11 is exposed, so that the remaining polishable material layer 12 is buried in the oxide film 11. The alignment mark structure 1 is formed which is the polishable material layer 12 buried in the oxide film 11.

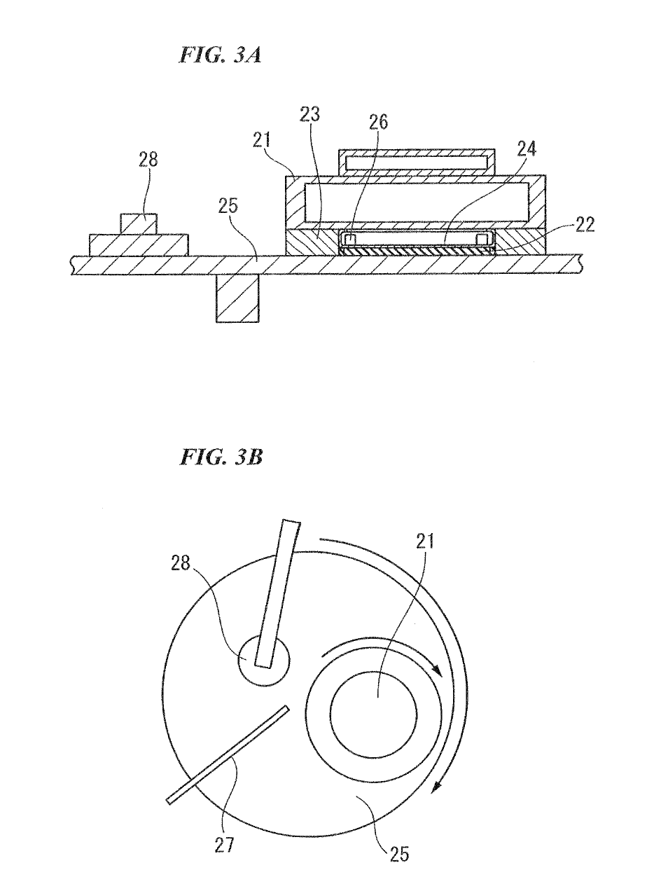

The chemical mechanical polishing process can be carried out by using a chemical mechanical polishing apparatus. FIG. 3A is a cross sectional elevation view illustrating a chemical mechanical polishing apparatus that can be used for carrying out the chemical mechanical polishing process. FIG. 3B is a plan view illustrating the chemical mechanical polishing apparatus of FIG. 3A.

The chemical mechanical polishing apparatus includes a polishing head 21 that polishes a semiconductor substrate 22, a retainer ring 23, a membrane 24 such as a neoprene rubber, a polishing pad 25, a peripheral presser 26, a slurry supply port 27, and a dresser 28.

The chemical mechanical polishing apparatus of FIG. 3A is used to polish the semiconductor substrate 22. The semiconductor substrate 22 is caught or held by the retainer ring 23 of the polishing head 21. Slurry is started to be supplied from the slurry supply port 27. The polishing head 21 is rotating, while the polishing pad 25 is rotating. The retainer ring 23 is made into contact with the polishing pad 25. A pressure is applied into an air chamber that is isolated by the membrane 24 in the polishing head 21. The membrane 24 is bulging to press the semiconductor substrate 22 uniformly to the polishing pad 25 so that the semiconductor substrate 22 is polished by the polishing pad 25.

The alignment mark structure 1 is used as follows. Position coordinates detection process is carried out. A position coordinate Xa of a position P1 is detected on the data detection line 13a. The position P1 is a position, on the data detection line 13a, of the first side wall of the first groove part 1c of the alignment mark structure 1. A position coordinate Xb of a position P2 is detected on the data detection line 13a. The position P2 is a position, on the data detection line 13a, of the other first side wall of the first groove part 1c of the alignment mark structure 1. A position coordinate Xc of a position P3 is detected on the data detection line 13a. The position P3 is a position, on the data detection line 13a, of the second side wall of the second groove part 1d of the alignment mark structure 1. A position coordinate Xd of a position P4 is detected on the data detection line 13a. The position P4 is a position, on the data detection line 13a, of the other second side wall of the second groove part 1d of the alignment mark structure 1. A specific position coordinate P0 is located on the data detection line 13a.

First to fourth distances of the position coordinates Xa, Xb, Xc and Xd from the specific position coordinate P0 are determined. An averaged distance of the first to fourth distances is calculated. The averaged distance is regarded as a distance of the groove 1a of the alignment mark structure 1 from the specific position coordinate P0, wherein the groove 1a includes the first groove part 1c and the second groove part 1d. The alignment is made using the averaged distance on the data detection line 13a between the specific position coordinate P0 and the groove 1a.

The alignment mark structure 1 includes the groove 1a. The groove 1a includes the first and second groove parts 1c and 1d. The first groove part 1c extends in the first direction. The second groove part 1d extends in the second direction that is perpendicular to the first direction. The top-edges of the first and second side walls of the first and second groove parts 1c and 1d are at least partially deformed by the polishing process. The position coordinates Xa, Xb, Xc and Xd correspond to positions P1, P2, P3 and P4 respectively of the alignment mark structure 1, wherein the positions P1, P2, P3 and P4 are crossing positions of the first side walls and the second side walls on the data detection line 13a. The first to fourth distances of the position coordinates Xa, Xb, Xc and Xd from the specific position coordinate P0 are determined. The averaged distance of the first to fourth distances is calculated. The averaged distance is regarded as the distance of the groove 1a of the alignment mark structure 1 from the specific position coordinate P0. Even if the deformation is caused on the top-edges of the first and second side walls of the first and second groove parts 1c and 1d due to some phenomenon such as dishing or erosion, a highly accurate alignment is possible on the following grounds. Even if shifts are caused of the position coordinates Xa and Xb, while other shifts are caused of the position coordinates Xc and Xd, the amounts of the shifts of the position coordinates Xa, Xb, Xc and Xd are canceled to each other. Thus, the use of the alignment mark structure 1 makes it possible to take place the highly accurate alignment.

The alignment mark structure 1 includes the groove 1a. The groove 1a includes the first and second groove parts 1c and 1d. The first groove part 1c extends in the first direction. The second groove part 1d extends in the second direction that is perpendicular to the first direction. Thus, the use of the alignment mark structure 1 makes it possible to take place the highly accurate alignment as compared to when an alignment mark structure includes a high density array of micro patterns.

The alignment mark structure 1 may preferably be disposed so that the first groove part 1c except for its side opposing portions crosses the data detection line 13a, and the second groove part 1d except for its side opposing portions crosses the data detection line 13a. More preferably, the center region of the first groove part 1c crosses the data detection line 13a, and the center region of the second groove part 1d crosses the data detection line 13a. These disposals of the alignment mark structure 1 may allow highly accurate detection of the position coordinates Xa, Xb, Xc and Xd that correspond to positions P1, P2, P3 and P4, respectively as compared to when side portions of the first and second groove parts 1c and 1d cross the data detection line 13a.

The alignment mark structure 1 includes the groove 1a. The groove 1a includes the first and second groove parts 1c and 1d. This structure allows the alignment mark structure 1 to be formed at high accuracy. The position coordinates Xa, Xb, Xc and Xd are detected on the data detection line 13a. The position coordinates Xa, Xb, Xc and Xd correspond to positions P1, P2, P3 and P4, on the data detection line 13a, of the first side walls of the first groove part 1c and the second side walls of the second groove part 1d. These detections of the position coordinates Xa, Xb, Xc and Xd results in that no errors are caused due to the mark shape in the direction crossing the data detection line 13a. As a result, highly accurate alignment coordinates can be obtained.

The alignment method is accomplished by using the alignment mark structure 1. The position coordinates detection process is carried out by detecting the position coordinates Xa, Xb, Xc and Xd and the specific position coordinate P0. The distance detection process is carried out as follows. The first to fourth distances of the position coordinates Xa, Xb, Xc and Xd from the specific position coordinate P0 are determined. The averaged distance of the first to fourth distances is calculated. The averaged distance is regarded as the distance of the groove 1a of the alignment mark structure 1 from the specific position coordinate P0. The highly accurate alignment process is carried out by using the averaged distance between the specific position coordinate P0 and the groove 1a.

The alignment mark structure should not be limited to the alignment mark structure 1 shown in FIG. 1A. In some cases, the alignment mark structure may include a plurality of first groove parts 1c and a second groove part 1d. In other cases, the alignment mark structure may include a first groove part 1c and a plurality of second groove parts 1d. In still other cases, the alignment mark structure may include a plurality of first groove parts 1c and a plurality of second groove parts 1d.

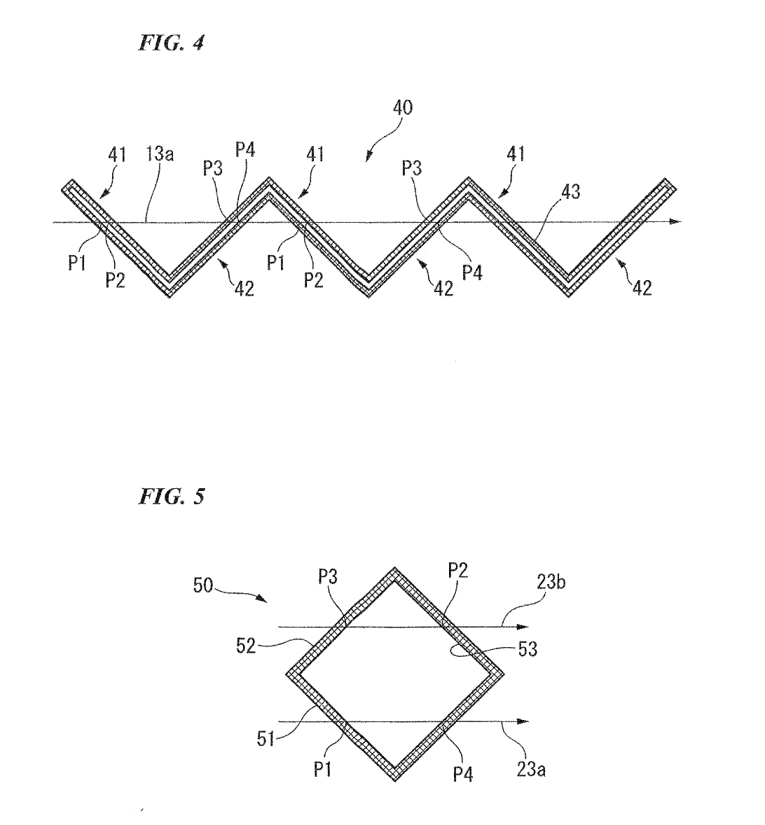

FIG. 4 is a plan view illustrating another alignment mark structure that includes a plurality of first groove parts and a plurality of second groove parts. An alignment mark structure 40 shown in FIG. 4 is different from the alignment mark structure 1 shown in FIG. 1A in the numbers and shape of combination of first groove parts 41 and second groove parts 42. The following descriptions will focus on the differences of the alignment mark structure 40 from the alignment mark structure 1.

The alignment mark structure 40 shown in FIG. 4 includes a groove 43. The groove 43 includes three first groove parts 41 and three second groove parts 42. The three first groove parts 41 and the three second groove parts 42 have the same length. The first groove parts 41 and the second groove parts 42 are arranged alternately. The first one of the second groove parts 42 connects between the first one of the first groove parts 41 and the second one of the first groove parts 41. The second one of the first groove parts 41 connects between the first one of second groove parts 42 and the second one of second groove parts 42. The second one of the second groove parts 42 connects between the second one of the first groove parts 41 and the third one of the first groove parts 41. The third one of the first groove parts 41 connects between the second one of second groove parts 42 and the third one of second groove parts 42.

Each of the three first groove parts 41 and the three second groove parts 42 crosses the data detection line 13a that is parallel to the tangential line of the rotational direction of the polishing pad 25. Each of the three first groove parts 41 and the three second groove parts 42 crosses the data detection line 13a at an angle of 45 degrees. The included angle between the three first groove parts 41 and the three second groove parts 42 is 90 degrees. The three first groove parts 41 are perpendicular to the three second groove parts 42.

The position coordinates Xa, Xb, Xc and Xd are detected on the data detection line 13a. The position coordinates Xa, Xb, Xc and Xd correspond to positions P1, P2, P3 and P4, on the data detection line 13a, of the first side walls of the first groove part 41 and the second side walls of the second groove part 42. The specific position coordinate that is not illustrated on the data detection line 13a is detected. First to fourth distances of the position coordinates Xa, Xb, Xc and Xd from the specific position coordinate are determined. An averaged distance of the first to fourth distances is calculated. The averaged distance is regarded as a distance of the groove 1a of the alignment mark structure 40 from the specific position coordinate. Even if the deformation is caused on the top-edges of the first and second side walls of the first and second groove parts 41 and 42 due to some phenomenon such as dishing or erosion, a highly accurate alignment is possible on the following grounds. Even if shifts are caused of the position coordinates Xa and Xb, while other shifts are caused of the position coordinates Xc and Xd, the amounts of the shifts of the position coordinates Xa, Xb, Xc and Xd are canceled to each other. Thus, the use of the alignment mark structure 40 makes it possible to take place the highly accurate alignment.

The alignment mark structure 40 includes the groove 43 that further includes the three first groove parts 41 and the three second groove parts 42. Three values of the position coordinates Xa are obtained. Three values of the position coordinates Xb are obtained. Three values of the position coordinates Xc are obtained. Three values of the position coordinates Xd are obtained. Thus, these detections of three sets of the position coordinates Xa, Xb, Xc and Xd improve the accuracy of alignment as compared to the alignment mark structure 1. As a result, highly accurate alignment coordinates can be obtained.

FIG. 5 is a plan view illustrating still another alignment mark structure that includes a plurality of first groove parts and a plurality of second groove parts. An alignment mark structure 40 shown in FIG. 5 is different from the alignment mark structure 1 shown in FIG. 1A in the numbers and shape of combination of first groove parts 41 and second groove parts 42 as well as in the number and placement of the data detection lines. The following descriptions will focus on the differences of the alignment mark structure 50 from the alignment mark structure 1.

The alignment mark structure 50 shown in FIG. 5 includes a groove 53. The groove 53 includes two first groove parts 51 and two second groove parts 52. The two first groove parts 51 extend in the first direction. The two second groove parts 52 extend in the second direction that is perpendicular to the first direction. The two first groove parts 51 and the two second groove parts 52 have the same length. The first groove parts 51 and the second groove parts 52 are arranged to form a square in plan view. The first one of the second groove parts 52 connects between the first one of the first groove parts 51 and the second one of the first groove parts 51. The second one of the second groove parts 52 connects between the first one of the first groove parts 51 and the second one of the first groove parts 51. The first one of the first groove parts 51 connects between the first one of the second groove parts 52 and the second one of the second groove parts 52. The second one of the first groove parts 51 connects between the first one of the second groove parts 52 and the second one of the second groove parts 52. The two first groove parts 51 extend in parallel to each other and in the first direction. The two second groove parts 52 extend in parallel to each other and in the first direction. The two second groove parts 52 are perpendicular to the two first groove parts 51. The two first groove parts 51 and the two second groove parts 52 have the same length. The alignment mark structure 50 has a square in plan view.

The alignment mark structure 50 shown in FIG. 5 includes the two first groove parts 51 and the two second groove parts 52 that have the same length as the two first groove parts 51. Thus, the groove 53 has a square shape in plan view. It is possible as a modification that the two second groove parts 52 are different in length from the two first groove parts 51, so that the groove 53 has a rectangular shape in plan view.

The alignment mark structure 50 shown in FIG. 5 crosses first and second data detection lines 23a and 23b which are parallel to each other. The first one of the two first groove parts 51 crosses the first data detection line 23a. The second one of the two first groove parts 51 crosses the second data detection line 23b. The first one of the two second groove parts 52 crosses the first data detection line 23a. The second one of the two second groove parts 52 crosses the second data detection line 23b.

The first and second data detection lines 23a and 23b are parallel to the tangential line of a rotational direction of the polishing pad 25. Each of the first one of the two first groove parts 51 and the first one of the two second groove parts 52 crosses the first data detection line 23a at an angle of 45 degrees. Each of the second one of the two first groove parts 51 and the second one of the two second groove parts 52 crosses the second data detection line 23b at an angle of 45 degrees. The included angle between the first groove part 51 and the second groove part 52 is 90 degrees. The first groove part 51 is perpendicular to the second groove part 52.

The position coordinates Xa and Xb, Xc and Xd are detected on the first and second data detection lines 23a and 23b. The position coordinates Xa and Xb are detected on the first data detection line 23a. The position coordinates Xc and Xd are detected on the second data detection line 23b. The position coordinates Xa, Xb, Xc and Xd correspond to positions P1, P2, P3 and P4, on the first and second data detection lines 23a and 23b, of the first side walls of the two first groove parts 51 and the two second groove parts 52. The first and second specific position coordinates that are not illustrated on the first and second data detection lines 23a and 23b are detected. Two sets of the first to fourth distances of the position coordinates Xa, Xb, Xc and Xd from the first and second specific position coordinates are determined. An averaged distance of the two sets of the first to fourth distances is calculated. The averaged distance is regarded as a distance of the groove 53 of the alignment mark structure 50 from the specific position coordinates.

The alignment mark structure 50 shown in FIG. 5 includes the groove 53 which includes two first groove parts 51 and two second groove parts 52. The two first groove parts 51 extend in the first direction. The two second groove parts 52 extend in the 5 second direction that is perpendicular to the first direction. The position coordinates Xa, Xb, Xc and Xd are detected on the first and second data detection lines 23a and 23b. The position coordinates Xa, Xb, Xc and Xd correspond to positions P1, P2, P3 and P4, on the first and second data detection lines 23a and 23b, of the first side walls of the two first groove parts 51 and the two second groove parts 52. Two sets of the first to fourth distances of the position coordinates Xa, Xb, Xc and Xd from the first and second specific position coordinates are determined. The averaged distance of the two sets of the first to fourth distances is calculated. The averaged distance is regarded as a distance of the groove 53 of the alignment mark structure 50 from the specific position coordinates. Even if the deformation is caused on the top-edges of the first and second side walls of the first and second groove parts 51 and 52 due to some phenomenon such as dishing or erosion, a highly accurate alignment is possible on the following grounds. Even if shifts are caused of the position coordinates Xa and Xb, while other shifts are caused of the position coordinates Xc and Xd, the amounts of the shifts of the position coordinates Xa, Xb, Xc and Xd are canceled to each other. Thus, the use of the alignment mark structure 50 makes it possible to take place the highly accurate alignment. As a result, highly accurate alignment coordinates can be obtained.

The alignment mark structure 50 includes the groove 53 that further includes the two first groove parts 51 and the two second groove parts 52. Two values of the position coordinates Xa are obtained. Two values of the position coordinates Xb are obtained. Two values of the position coordinates Xc are obtained. Two values of the position coordinates Xd are obtained. Thus, these detections of two sets of the position coordinates Xa, Xb, Xc and Xd improve the accuracy of alignment as compared to the alignment mark structure 1. As a result, highly accurate alignment coordinates can be obtained.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. An alignment mark structure comprising:
a first pair of first side walls facing each other and extending in a first direction, the first pair of first side walls crossing a first data detection line; and
a second pair of second side walls facing each other and extending in a second direction, the second pair of second side walls crossing the first data detection line, and the second direction being different from the first direction.

2. The alignment mark structure according to claim 1, wherein the first pair of first side walls defines a first groove and the second pair of second side walls defines a second groove.

3. The alignment mark structure according to claim 1, wherein the first data detection line is parallel to an edge line of a semiconductor chip.

4. The alignment mark structure according to claim 1, wherein the first data detection line is perpendicular to an edge line of a semiconductor chip.

5. The alignment mark structure according to claim 1, wherein the first direction is non-parallel to an edge line of a semiconductor chip.

6. The alignment mark structure according to claim 1, wherein the first and second directions cross to each other at the right angle.

7. The alignment mark structure according to claim 1, wherein the first direction crosses the first data detection line at an angle in the range of 20 degrees to 70 degrees.

8. The alignment mark structure according to claim 1, wherein the first direction crosses the first data detection line at an angle of 45 degrees.

9. The alignment mark structure according to claim 1, further comprising:
a third pair of third side walls facing each other and extending in the first direction, the third pair of third side walls crossing the first data detection line.

10. The alignment mark structure according to claim 1, further comprising:
a fourth pair of second side walls facing each other and extending in the second direction, the fourth pair of fourth side walls crossing the first data detection line.

11. The alignment mark structure according to claim 1, further comprising:
a third pair of third side walls facing each other and extending in the first direction, the third pair of third side walls crossing a second data detection line that is parallel to the first data detection line; and
a fourth pair of second side walls facing each other and extending in the second direction, the fourth pair of fourth side walls crossing the second data detection line,
wherein a set of the first to fourth pairs of first to fourth side walls forms a rectangle in plan view.

12. An alignment mark structure comprising:
a first pair of first side walls facing each other and extending in a first direction, the first pair of first side walls crossing a data detection line, the first pair of first side walls defining a first groove, and the first pair of first side walls having a first top surface that comprises a first polished surface; and
a second pair of second side walls facing each other and extending in a second direction, the second pair of second side walls crossing the data detection line, the second direction being different from the first direction, the second pair of second side walls defining a second groove, and the second pair of second side walls having a second top surface that comprises a second polished surface,
wherein a first one of the first side walls has a first positional coordination point on the data detection line, the first positional coordination point representing a first crossing position of the first one of the first side walls and the data detection line, the first positional coordination point having a first distance from a reference coordination point on the data detection line,
a second one of the first side walls has a second positional coordination point on the data detection line, the second positional coordination point representing a second crossing position of the second one of the first side walls and the data detection line, the second positional coordination point having a second distance from the reference coordination point,
a first one of the second side walls has a third positional coordination point on the data detection line, the third positional coordination point representing a third crossing position of the first one of the second side walls and the data detection line, the third positional coordination point having a third distance from the reference coordination point,
a second one of the second side walls has a fourth positional coordination point on the data detection line, the fourth positional coordination point representing a fourth crossing position of the second one of the second side walls and the data detection line, the fourth positional coordination point having a fourth distance from the reference coordination point, and
wherein the average value of the first to fourth distances is detected as a distance between the reference coordination point and a groove of the alignment mark structure, where the first to fourth grooves form the groove of the alignment mark structure.

13. The alignment mark structure as claimed in claim 12, wherein the first direction is non-parallel to a tangential line of a rotational direction of a polishing pad to be used for polishing.

14. The alignment mark structure according to claim 12, further comprising:
a third pair of third side walls facing each other and extending in the first direction, the third pair of third side walls crossing the data detection line.

15. The alignment mark structure according to claim 12, further comprising:
a fourth pair of second side walls facing each other and extending in the second direction, the fourth pair of fourth side walls crossing the data detection line.

16. The alignment mark structure according to claim 12, further comprising:
a third pair of third side walls facing each other and extending in the first direction, the third pair of third side walls crossing a second data detection line that is parallel to the first data detection line; and
a fourth pair of second side walls facing each other and extending in the second direction, the fourth pair of fourth side walls crossing the second data detection line,
wherein a set of the first to fourth pairs of first to fourth side walls forms a rectangle in plan view.

17. An alignment method comprising:
detecting a first positional coordination point on a first data detection line, the first positional coordination point representing a first crossing position between the first data detection line and a first one of first paired side walls facing each other and extending in a first direction, the first paired side walls crossing the first data detection line;
detecting a second positional coordination point on the first data detection line, the second positional coordination point representing a second crossing position between the first data detection line and a second one of the first paired side walls;
detecting a third positional coordination point on the first data detection line, the third positional coordination point representing a third crossing position between the first data detection line and a first one of second paired side walls facing each other and extending in a second direction, the second direction being different from the first direction, the second paired side walls crossing the first data detection line;
detecting a fourth positional coordination point on the first data detection line, the fourth positional coordination point representing a fourth crossing position between the first data detection line and a second one of the second paired side walls;
detecting a first distance of the first positional coordination point from a reference coordination point on the first data detection line;
detecting a second distance of the second positional coordination point from the reference coordination point on the first data detection line;
detecting a third distance of the third positional coordination point from the reference coordination point on the first data detection line;
detecting a fourth distance of the fourth positional coordination point from the reference coordination point on the first data detection line; and
calculating an averaged value from the first to fourth distances, the averaged value being regarded as a distance between the reference coordination point and a groove of the alignment mark structure, where the first to fourth grooves form the groove of the alignment mark structure.

18. The alignment method according to claim 17, wherein the first data detection line is parallel or perpendicular to an edge line of a semiconductor chip.

19. The alignment method according to claim 17, wherein the first direction is non-parallel to an edge line of a semiconductor chip.

20. The alignment method according to claim 17, further comprising:
detecting a fifth positional coordination point on a second data detection line, the second data detection line being parallel to the first data detection line, the fifth positional coordination point representing a fifth crossing position between the second data detection line and a first one of third paired side walls facing each other and extending in the first direction, the third paired side walls crossing the second data detection line;
detecting a sixth positional coordination point on the second data detection line, the sixth positional coordination point representing a sixth crossing position between the second data detection line and a second one of the second paired side walls;
detecting a seventh positional coordination point on the second data detection line, the seventh positional coordination point representing a seventh crossing position between the second data detection line and a first one of fourth paired side walls facing each other and extending in the second direction, the second direction being different from the first direction, the fourth paired side walls crossing the second data detection line;
detecting an eighth positional coordination point on the second data detection line, the eighth positional coordination point representing an eighth crossing position between the second data detection line and a second one of the fourth paired side walls;
detecting a fifth distance of the fifth positional coordination point from the reference coordination point on the first data detection line;
detecting a sixth distance of the sixth positional coordination point from the reference coordination point on the first data detection line;
detecting a seventh distance of the seventh positional coordination point from the reference coordination point on the first data detection line; and
detecting an eighth distance of the eighth positional coordination point from the reference coordination point on the first data detection line,
wherein calculating the averaged value comprises calculating an averaged value from the first to eighth distances.
